(19) United States
(12) Patent Application Publication
(10) Pub. No.: US 2009/0235978 A1
(43) Pub. Date: Sep. 24, 2009

(54) METHOD FOR PRODUCING PHOTOACTIVE LAYERS AND COMPONETS COMPRISING SAID LAYER(S)

(75) Inventors: Monika Sofie Piber, Anger (AT); Gregor Trimmel, Graz (AT); Franz Stelzer, Graz (AT); Thomas Rath, Graz (AT); Albert K. Plessing, Brunn (AT); Dieter Meissner, Wels (AT)

Correspondence Address: YOUNG & THOMPSON, 209 Madison Street, Suite 500, ALEXANDRIA, VA, 22314, US

(73) Assignee: ISOVOLTA AG, Wiener Neudorf (AT)

(21) Appl. No.: 12/306,136

(22) PCT Filed: Jun. 18, 2007
(86) PCT No.: PCT/AT2007/000296

§ 371 Date: Mar. 23, 2009

(30) Foreign Application Priority Data
Jun. 22, 2006 (AT) A 1058/2006

(51) Int. Cl. H01L 31/0256; H01L 31/18

(52) U.S. Cl. 136/252; 438/82; 257/E31.003

(57) ABSTRACT

A method for producing photoactive layers, and components, such as solar cells, including the layers. According to the invention, the photoactive layers are produced by forming a non-semiconducting layer from precursor material including at least one metal compound and a salt-like and/or organic reactant on a substrate by printing or blade coating, the layer being exposed to temperatures of less than 300° C., wherein a semiconducting, photoactive layer is formed from the non-semiconducting layer by thermal conversion of the precursor material.

The invention relates to a process for the production of photoactive layers as well as components that comprise this (these) layer(s).

Semiconductive metal sulfides, selenides and tellurides, in particular CuInS₂, CuInSe₂, CdSe, ZnS, and ZnSe, are important materials for the formation of photoactive layers, which are useful, i.a., for photovoltaic applications. Thus, semiconductive metal sulfides are used in the form of thin layers for inorganic solar cells, so-called ETA (Extreme Thin Absorber) cells. A combination of layers that consists of semiconductive metal sulfides with a conjugated semiconductive polymer or another layer that consists of electroactive, organic molecules results in a two-layer design, which is also suitable for the production of photoactive elements.

For the production of such semiconductive layers, known processes such as reactive or non-reactive sputtering (cathode evaporation), separation by glow discharge, conventional thermal evaporation, chemical and electrochemical separation, spraying process (spraying pyrolysis), the sulfurization of metal films^{[1-5]}, and expensive processes for the production of epitaxial layers are available.

For most of these processes—except for the electrochemical application^{[6-9]}—relatively high temperatures, i.e., temperatures above 300° C., are necessary for the production of the photoactive layers. A production of these semiconductor layers is carried out by thermal decomposition of a reactant in the presence of the corresponding metal ions. Similar reaction mixtures are used in spray-pyrolysis^{[10-29]}.

Castro, Bailey et al.^{[30]} describe a process for the production of a copper indium sulfide complex at low temperatures. However, according to this process, relatively expensive starting compounds are used.

A similar process based on the spray chemical vapor deposition under atmospheric conditions is also described by Harris et al.^{[31]} To decompose the starting compounds that are used, temperatures of 200-300° C. are used.

Cui et al. describe another process for the production of semiconductive copper indium sulfide.^{[32]} The latter produce CuInS₂ and AgInS₂ in the form of semiconductive nanorods that consist of a stoichiometric mixture of In(S₂CNEt₂)₃ and Cu(S₂CNEt₂)₂ or Ag(S₂CNEt₂) according to the principle of colloidal synthesis, whereby the thioketones that accumulate as by-products with ethylenediamine at 195° C. have to be removed in a solvothermal process.

The object of this invention is therefore to provide a process for the production of photoactive layers that is easy to perform and that can be performed, on the one hand, at low temperatures, as well as, on the other hand, under direct use of metal compounds and reactants that are easy to synthesize. According to the invention, a process of the above-mentioned type is proposed, which is characterized in that a non-semiconductive layer is formed from precursor material that comprises at least one metal compound and one salt-like and/or organic reactant on a substrate by pressing or knife-coating, and said non-semiconductive layer is exposed to temperatures of less than 300° C., whereby a semiconductive photoactive layer is formed from the non-semiconductive layer by thermal conversion of the precursor material.

Precursor material is defined according to this invention as a non-semiconductive material that consists of a metal compound, such as metal salts and/or metal complexes, and a salt-like or organic compound that in a conversion step releases an additional component that is necessary for semiconductor formation.

Additional advantageous embodiments of the process according to the invention are disclosed according to subclaims.

The invention also relates to components such as solar cells or photodetectors that comprise the layers that are produced according to the invention.

The reaction temperature of the decomposition reaction can advantageously lie significantly below 300° C., especially when the reaction is catalyzed by an acid or base, and/or acidic or alkaline starting compounds are used.

Advantageously, the conversion takes place in the presence of a Lewis base, for example pyridine. Lewis bases act as complexing agents for the metal ions that are used. Lewis bases also play a decisive role in the decomposition reaction of the reactant, for example in the production of chalcogenides with thioacetamide as a sulfur source. By the provision of a free electron pair of the Lewis base, possible conversion reactions are accelerated.

Examples of Lewis bases are F⁻, OH⁻, O²⁻, H₂O, NH₃ and its derivatives, Br⁻, N₃⁻, NO₂⁻, I⁻, S², and SCN⁻. Lewis bases that are used according to the invention are primarily nitrogen-containing organic bases, such as pyridine and/or derivatives of pyridine, various primary, secondary and/or tertiary amines, nitrogen-containing heterocyclic compounds, deprotonated amino acids and/or bases with a pyrimidine skeleton.

By these especially low production temperatures, it is possible to produce semiconductor layers both on inorganic substrates, such as metals, or glass, but also on polymer films. The latter represents a quite special advantage relative to the already known production methods. The reaction conditions can be selected so that the semiconductors are present in the layer in nanocrystalline form or as nanoparticles.

The mixture of the starting substances can be present both in solution and as slurry (suspension), as dispersion, or as paste.

With the process according to the invention, metal compounds are used as semiconductor particles, which can react with a salt-like or organic reactant.

The metal compound(s), which is (are) used as (a) starting compound(s), can also be a salt-like compound.

In a like manner, the metal compound can be an organometallic compound or an organometallic complex.

The metal compound(s) used can have both basic and acidic properties, which makes possible the conversion at lower temperatures or catalytically influences the conversion.

A high current yield of the components in the form of solar cells is thus achieved, in that the inorganic materials are particles whose grain size is preferably between 0.5 nm and 500 nm.

In solar cells, the semiconductive layers according to the invention can act as both electron donors and electron acceptors.

When using certain starting compounds, the conversion temperature in a semiconductor can also be less than 100° C.

The conversion of the starting compounds in the semiconductor can be carried out in the presence of an acid.

The conversion of the starting compounds in the semiconductor can be carried out in a likewise advantageous way in the presence of a base.

The reaction temperature can be adjusted by thermal treatment but also by photons with energy of greater than 1 (one) eV.

By the process according to the invention, components that consist of a substrate and a photoactive layer applied thereon can advantageously be produced.

The application is carried out by printing by known printing methods, such as flexographic printing or intaglio printing, or by knife-coating the semiconductor onto the substrate.

The invention is explained in more detail below based on the embodiments as well as the figures.

### EXAMPLE 1

### Process for the Production of Semiconductive Copper Indium Sulfide Layers

The production of copper indium sulfide layers is carried out by reaction of thioacetamide as a sulfur-containing reactant in the presence of a copper and indium salt, whereby thioacetamide is decomposed. In this production process, by way of example, InCl₃ and CuI are complexed in pyridine. Thiourea is dissolved in this solution. This reaction solution is dripped onto a suitable substrate, such as indium tin oxide on glass, an organic polymer or an electroactive organic polymer, and is heated to 200° C. under inert gas atmosphere (e.g., nitrogen, argon, helium).

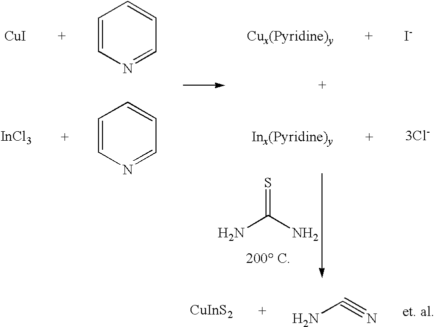

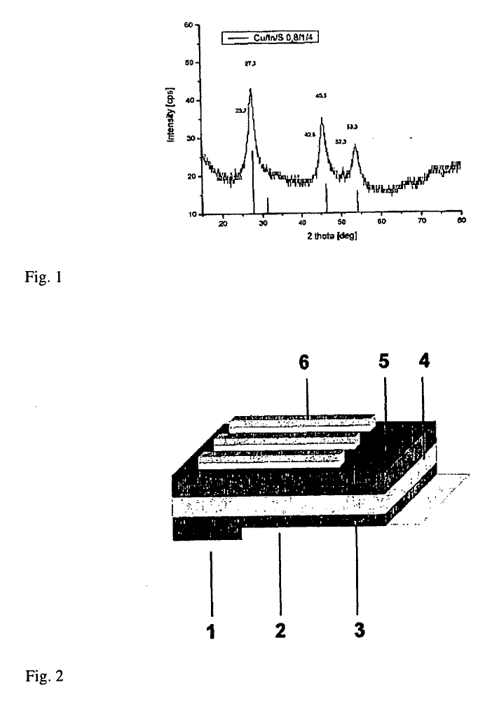

The layers that are obtained are examined by means of x-ray structural analysis (XRD). In this case, FIG. 1 shows the x-ray diffractogram of such a sample. The peaks at 27°, 45°, and 55°, which can be associated with CuInS₂, have a significant widening by their nanocrystalline nature.

### EXAMPLE 2

### Production of an Inorganic/Organic Hybrid Solar Cell

The primary design of this hybrid solar cell is depicted in FIG. 2. As a carrier 1, a glass substrate or a transparent polymer film is used.

For the production of solar cells, a portion of the ITO layer (indium/tin oxide layer) 2 is removed by chemical or physical etching.

To offset the roughness of the layer, a polyethylene dioxythiophene (PEDOT:PSS) layer 3 can optionally be applied. This step can be omitted, however. In the next step, a layer 4 that consists of an organic electroactive polymer or a low-molecular organic electroactive substance is applied. Polymer solutions are preferably applied from suspensions or homogenous solutions by spin-coating, dip-coating, knife-coating, pressing or spraying. Low-molecular substances can also be applied by evaporation coating.

A CuInS₂ layer, as produced according to Example 1 (layer 5), is now applied on this layer.

The electrodes 6, e.g., aluminum, gold, silver, or a combination of calcium/gold, calcium/aluminum, magnesium/gold are then applied on this layer by evaporation coating or sputtering.

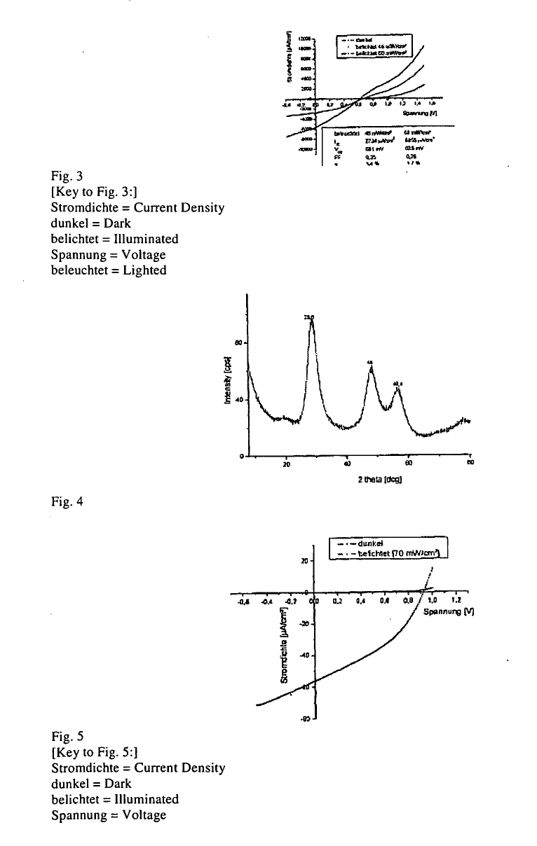

In FIG. 3, the current/voltage characteristics of the hybrid solar cell are shown according to FIG. 2.

The latter show a V_{oc}, (open terminal voltage) of 625 mV and an I_{SC} (short-circuit current) of 5.855 mA/cm² at an illumination of 60 mW/cm². The filling factor is 29%, and a degree of efficiency of 1.7% was achieved.

### EXAMPLE 3

### Process for the Production of Semiconductive Zinc Sulfide Layers

The production of zinc sulfide layers is carried out by decomposing thioacetamide in the presence of zinc acetate. The decomposition was performed in this case at 150° C. The x-ray diffractogram in FIG. 4 shows the formed nanocrystalline ZnS phase. As a crystallographic phase, sphalerite could be identified. The width of the reflexes confirms the presence of primary crystallites in the nanometer range.

As an application for such a layer, a bilayer heterojunction solar cell was produced, whose degree of efficiency was characterized by means of a U/I characteristic (see FIG. 5). The solar cell that was produced in this way shows an especially high photoelectric voltage of 920 mV.

### EXAMPLE 4

### Process for the Production of a CuGaS₂ Layer

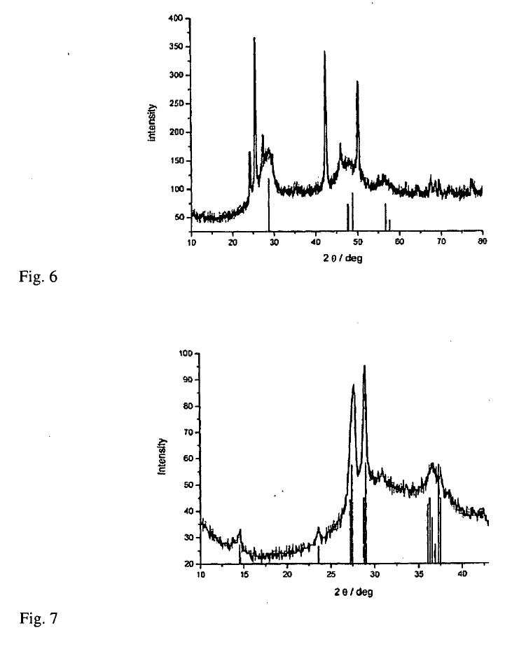

For the production of a CuGaS₂ layer, 31.5 mg of CuI, 37.9 mg of GaCl₃ and 64.5 mg of thioacetamide are dissolved in pyridine and applied to a glass substrate. This layer is heated under inert gas atmosphere for 30 minutes at 200° C., whereby the conversion is carried out in a CuGaS₂ layer. FIG. 6 shows a diffractogram of the nanocrystalline semiconductor layer that is formed, whereby the peaks that are characteristic of the CuGaS₂ lie at 29°, 48°, 49°, and 57°. The sharp peaks at 24°, 25.5°, 27.5°, 42°, 46.5° and 50° originate from small amounts of the educt CuI, which was not completely reacted. By an increase of the gallium components, these educt peaks can be eliminated.

### EXAMPLE 5

### Process for the Production of a Copper Iron Sulfide Layer

Analogously to Example 4, a copper iron sulfide layer was produced. To this end, 31.5 mg of CuI, 71.4 mg of FeCl₃.6H₂O and 79.3 mg of thioacetamide, dissolved in pyridine, were used. In the XRD analysis of the formed material, the peaks that were characteristic of copper iron sulfides were found at 29°, 34°, 53.5° and 57.5°. The width of the peaks in turn indicates the formation of nanocrystalline copper iron sulfide.

### EXAMPLE 6

### Process for the Production of a Silver Gallium Sulfide Layer

Here, it is shown that it is also possible in the ternary sulfides to exchange the copper atoms by other divalent atoms. In this test, 28.1 mg of AgNO₃, 37.8 mg of GaCl₃ and 64.4 mg of thiourea were dissolved in pyridine, and a silver gallium sulfide layer was produced analogously to Example 4. The diffractogram depicted in FIG. 7 confirms the formation of the silver-rich silver gallium sulfide phase Ag₉GaS₆, which shows the characteristic peaks at 19.1°, 23.3°, 27.3° (double peak), 28.7° (double peak), 33.2° and the 7 reflexes lying between 36.0° and 37.5.°

In addition to these precisely-described experiments, a number of other studies were performed in which there could be shown that
1) in addition to the elements Cu, In, Zn, and S, the elements Ag, Cd, Ga, Al, Pb, Hg, Se, and Te can also be used;
2) except for thioacetamide, the following S-compounds can also be used: elementary sulfur, elementary sulfur and a vulcanization accelerator, thiourea, thiuram, hydrogen sulfide, metal sulfides, hydrogen sulfides, CS₂, P₂S₅;
3) in addition to the metal salts, organometallic compounds such as acetates, metal thiocarbamide compounds can also be used.

In summary, it can be stated that with the process according to the invention, semiconductive layers, in particular in nanocrystalline form, that exhibit satisfactory degrees of efficiency in hybrid solar cells and in pure inorganic semiconductor layers can be produced in an energy-efficient way.
[1] V. Alberts, J. Titus, R. W. Birkmire, Thin Solid Films 2004, 451, 207.
[2] A. Antony, A. S. Asha, R. Yoosuf, R. Manoj, M. K. Jayaraj, Solar Energy Materials and Solar Cells 2004, 81, 407.
[3] B. M. Basol, Thin Solid Films 2000, 361-362, 514.
[4] C. Dzionk, H. Metzner, S. Hessler, H.-E. Mahnke, Thin Solid Films 1997, 299, 38.
[5] M. Nanu, L. Reijnen, B. Meester, J. Schoonman, A. Goossens, Chemical Vapor Deposition 2004, 10, 45.
[6] S. Bereznev, I. Konovalov, A. Opik, J. Kois, E. Mellikov, Solar Energy Materials and Solar Cells 2005, 87, 197.
[7] S. Bereznev, I. Konovalov, J. Kois, E. Mellikov, A. Opik, Macromolecular Symposia 2004, 212, 287.
[8] S. Bereznev, I. Konovalov, A. Opik, J. Kois, Synthetic Metals 2005, 152, 81.
[9] S. Nakamura, A. Yamamoto, Solar Energy Materials and Solar Cells 2003, 75, 81.
[10] M. C. Zouaghi, T. Ben Nasrallah, S. Marsillac, J. C. Bemede, S. Belgacem, Thin Solid Films 2001, 382, 39.
[11] H. Bihri, M. Abd-Lefdil, Thin Solid Films 1999, 354, 5.
[12] H. Bouzouita, N. Bouguila, A. Dhouib, Renewable Energy 1998, 00, 1.
[13] T. T. John, M. Mathew, C. S. Kartha, K. P. Vijayakumar, T. Abe, Y. Kashiwaba, Solar Energy Materials and Solar Cells 2005, 89, 27.
[14] T. T. John, K. C. Wilson, P. M. R. Kumar, C. S. Kartha, K. P. Vijayakumar, Y. Kashiwaba, T. Abe, Y. Yasuhiro, Physica Status Solidi a-Applied Research 2005, 202, 79.
[15] M. Krunks, O. Bijakina, E. Mellikov, T. Varema, Ternary and Multinary Compounds 1998, 152, 325.
[16] M. Krunks, O. Bijakina, V. Mikli, H. Rebane, T. Varema, M. Altosaar, E. Mellikov, Solar Energy Materials and Solar Cells 2001, 69, 93.
[17] M. Krunks, O. Bijakina, T. Varema, V. Mikli, E. Mellikov, Thin Solid Films 1999, 338, 125.
[18] M. Krunks, O. Kijatkina, A. Mere, T. Varema, I. Oja, V. Mikli, Solar Energy Materials and Solar Cells 2005, 87, 207.
[19] M. Krunks, O. Kijatkina, H. Rebane, I. Oja, V. Mikli, A. Mere, Thin Solid Films 2002, 403, 71.
[20] M. Krunks, T. Leskela, R. Mannonen, L. Niinisto, Journal of Thermal Analysis and Calorimetry 1998, 53, 355.
[21] M. Krunks, T. Leskela, I. Mutikainen, L. Niinisto, Journal of Thermal Analysis and Calorimetry 1999, 56, 479.
[22] M. Krunks, E. Mellikov, O. Bijakina, Physica Scripta 1997, T69, 189.
[23] M. Krunks, V. Mikli, O. Bijakina, E. Mellikov, Applied Surface Science 1999, 142, 356.
[24] M. Krunks, V. Mikli, O. Bijakina, H. Rebane, A. Mere, T. Varema, E. Mellikov, Thin Solid Films 2000, 361, 61.
[25] J. Madarasz, P. Bombicz, M. Okuya, S. Kaneko, Solid State Ionics 2001, 141, 439.
[26] A. Mere, O. Kijatkina, H. Rebane, J. Krustok, A. Krunks, Journal of Physics and Chemistry of Solids 2003, 64, 2025.
[27] M. Nanu, J. Schoonman, A. Goossens, Nano Letters 2005, 5, 1716.
[28] M. Nanu, J. Schoonman, A. Goossens, Advanced Functional Materials 2005, 15, 95.
[29] M. Nanu, J. Schoonman, A. Goossens, Advanced Materials 2004, 16, 453.
[30] S. L. Castro, S. G. Bailey, R. P. Raffaelle, K. K. Banger, A. F. Hepp, Chemistry of Materials 2003, 15, 3142.
[31] J. D. Harris, K. K. Banger, D. A. Scheiman, M. A. Smith, M. H. C. Jin, A. F. Hepp, Materials Science and Engineering B-Solid State Materials for Advanced Technology 2003, 98, 150.
[32] Y. Cui, J. Ren, G. Chen, Y. Qian, Y. Xie, Chemistry Letters 2001, 30, 236.

1. Process for the production of photoactive layers, characterized in that a non-semiconductive layer is formed from precursor material that comprises at least one metal compound and a salt-like and/or organic reactant on a substrate by pressing or knife-coating, and said non-semiconductive layer is exposed to temperatures of less than 300° C., whereby a semiconductive, photoactive layer is formed from the non-semiconductive layer by thermal conversion of the precursor material.

2. Process according to claim 1, wherein the metal compound is a metal salt.

3. Process according to claim 1, wherein the metal compound is a metal complex.

4. Process according to claim 1, wherein the metal compound is selected from the group of sulfides, selenides and tellurides.

5. Process according to claim 1, wherein the metal compound is selected from the group of carbides, phosphides, nitrides, antimonides and arsenides.

6. Process according to claim 1, wherein a sulfur-releasing reactant that is selected from the group of elementary sulfur, elementary sulfur with a vulcanization accelerator, thioacetamide, thiourea, thiuram, hydrogen sulfide, metal sulfides and hydrogen sulfides, CS₂, P₂S₂ or the corresponding tellurium and/or selenium compounds is used.

7. Process according to claim 1, wherein the thermal conversion is carried out in the presence of a Lewis Base.

8. Process according to claim, wherein the substrate that is used is a semiconductive polymer and/or oligomer or a semiconductive, monomolecular organic compound.

9. Process according to claim 1, wherein the semiconductive, photoactive layer that is formed is present in the form of nanoparticles.

10. Component, wherein the latter comprises a semiconductive, photoactive layer that is produced according to a process according to claim 1.

11. Component according to claim 10, wherein the component is a solar cell.
